(19) United States
(12) Patent Application Publication
(10) Pub. No.: US 2024/0222163 A1
(43) Pub. Date: Jul. 4, 2024

(54) SUBSTRATE PROCESSING APPARATUS AND SEMICONDUCTOR MANUFACTURING EQUIPMENT INCLUDING THE SAME

(71) Applicant: SEMES CO., LTD., Cheonan-si (KR)

(72) Inventors: Ju Won KIM, Gyeonggi-do (KR); Dongwoon PARK, Seoul (KR); Gi Hun JUNG, Chungcheongnam-do (KR); Byoung Doo CHOI, Chungcheongnam-do (KR); A Rah CHO, Daejeon (KR); Jong Hyuk PARK, Chungcheongnam-do (KR)

(73) Assignee: SEMES CO., LTD., Cheonan-si (KR)

(21) Appl. No.: 18/505,474

(22) Filed: Nov. 9, 2023

(30) Foreign Application Priority Data
Dec. 30, 2022 (KR) 10-2022-0190993

(51) Int. Cl. H01L 21/67; G03F 7/38

(52) U.S. Cl. CPC H01L 21/67115; G03F 7/38; H01L 21/67225

(57) ABSTRACT

Provided is a substrate processing apparatus that processes a semiconductor substrate using a laser and a semiconductor manufacturing equipment including the same. The substrate processing apparatus comprises a chamber for providing a space where a substrate is processed; a support module disposed within the chamber and for supporting the substrate; and a laser signal generation module disposed in the chamber and for transmitting a laser signal onto the substrate to heat-treat the substrate, wherein the laser signal generation module heat-treats the substrate including a photoresist layer.

This application claims the benefit of Korean Patent Application No. 10-2022-0190993, filed on Dec. 30, 2022, in the Korean Intellectual Property Office, the disclosure of which is incorporated herein by reference in its entirety.

### BACKGROUND

### 1. Field

The present disclosure relates to a substrate processing apparatus and a semiconductor manufacturing equipment including the same. More specifically, it relates to a substrate processing apparatus that can be applied to a photolithography process and a semiconductor manufacturing equipment including the same.

### 2. Description of the Related Art

The semiconductor manufacturing process can be performed continuously within a semiconductor manufacturing equipment and can be divided into preprocess and postprocess. Here, the preprocess refers to the process of completing a semiconductor chip by forming a circuit pattern on a semiconductor substrate (e.g., wafer), and the postprocess refers to the process of evaluating the performance of the product completed through the preprocess.

Semiconductor manufacturing equipment can be installed in a semiconductor manufacturing plant, defined as a fab, to manufacture semiconductors. A semiconductor substrate can be moved to an equipment where each process is performed to sequentially go through each process for producing a semiconductor, such as deposition process, photolithography process, etching process, ashing process, ion implantation process, cleaning process, packaging process, and inspection process.

The photolithography process is a process of forming a pattern on a semiconductor substrate and consists of a coating process, exposure process, development process, and bake process. Here, the bake process is a process of heat-treating a semiconductor substrate, and may be performed before or after the coating process, exposure process, development process, etc.

In the bake process, the semiconductor substrate is placed on a support unit within the chamber, and the semiconductor substrate is heated using a heater installed within the support unit. However, in such a hot plate baking process, a convection phenomenon may occur due to temperature deviation within the chamber, and in addition to temperature loss discharged through the exhaust, non-uniformity may occur in the surface temperature of the semiconductor substrate. The temperature non-uniformity may cause non-uniform pattern line width (thickness deviation) during the fine pattern formation process and reduce process yield.

### SUMMARY

The technical problem to be solved by the present disclosure is to provide a substrate processing apparatus that processes a semiconductor substrate using a laser and a semiconductor manufacturing equipment including the same.

The technical objects of the present disclosure are not limited to the technical objects mentioned above, and other technical objects not mentioned will be clearly understood by those skilled in the art from the description below.

One aspect of the substrate processing apparatus of the present disclosure for achieving the above object comprises a chamber for providing a space where a substrate is processed; a support module disposed within the chamber and for supporting the substrate; and a laser signal generation module disposed in the chamber and for transmitting a laser signal onto the substrate to heat-treat the substrate, wherein the laser signal generation module heat-treats the substrate including a photoresist layer.

One aspect of the semiconductor manufacturing equipment of the present disclosure for achieving the above object comprises a transfer module including a substrate transport robot for transporting a substrate; a plurality of first substrate processing apparatuses disposed on one side of the transfer module; and a plurality of second substrate processing apparatuses disposed on the other side of the transfer module, wherein the first substrate processing apparatus comprises a chamber for providing a space where a substrate is processed; a support module disposed within the chamber and for supporting the substrate; and a laser signal generation module disposed in the chamber and for transmitting a laser signal onto the substrate to heat-treat the substrate, wherein the laser signal generation module heat-treats the substrate including a photoresist layer.

Another aspect of the substrate processing apparatus of the present disclosure for achieving the above object comprises a chamber for providing a space where a substrate is processed; a support module disposed within the chamber and for supporting the substrate; and a laser signal generation module disposed in the chamber and for transmitting a laser signal onto the substrate to heat-treat the substrate, wherein the substrate includes a plurality of layers, wherein the laser signal generation module selectively heats some layers among the plurality of layers, and the some layers include the photoresist layer and a polymer layer, wherein the laser signal generation module transmits a laser signal in a Mid-IR band, and the laser signal has a wavelength of 3 μm to 50 μm, wherein the laser signal generation module incidents the laser signal on the substrate in a first direction, where the first direction is perpendicular to a width direction of the substrate, wherein a scanning direction of the laser signal is perpendicular to an emission direction of the laser signal.

Details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a first exemplary diagram schematically showing the internal structure of a semiconductor manufacturing equipment including a plurality of process chambers;

FIG. 2 is a second exemplary diagram schematically showing the internal structure of a semiconductor manufacturing equipment including a plurality of process chambers;

FIG. 3 is a plan view schematically showing the internal structure of a substrate processing apparatus that performs a heat treatment process on a semiconductor substrate;

FIG. 4 is a cross-sectional view schematically showing the internal structure of a substrate processing apparatus that performs a heat treatment process on a semiconductor substrate;

FIG. 5 is a cross-sectional view schematically showing the internal structure of a substrate processing apparatus that performs a development process on a semiconductor substrate;

FIG. 6 is a diagram schematically showing the internal structure of a heating unit in a first substrate processing apparatus including a laser signal generation module;

FIG. 7 is an example diagram for explaining the heating module within the plate constituting the heating unit;

FIG. 8 is an exemplary diagram for explaining the internal structure of the laser signal generation module constituting the heating unit;

FIG. 9 is a first example diagram for explaining the performance of the laser signal generation module constituting the heating unit;

FIG. 10 is an example diagram for explaining the internal structure of a semiconductor substrate heat treated by a laser signal generation module;

FIG. 11 is a second example diagram for explaining the performance of the laser signal generation module constituting the heating unit;

FIG. 12 is a third example diagram for explaining the performance of the laser signal generation module constituting the heating unit;

FIG. 13 is a first example diagram for explaining the performance of the support module and stage constituting the heating unit;

FIG. 14 is a second example diagram for explaining the performance of the support module and stage constituting the heating unit;

FIG. 15 is an example diagram for explaining a method of processing a

semiconductor substrate according to the operation of a laser signal generation module or stage;

FIG. 16 is a first example diagram for explaining various arrangement structures of a plurality of process chambers in a semiconductor manufacturing equipment;

FIG. 17 is a second example diagram for explaining various arrangement structures of a plurality of process chambers in a semiconductor manufacturing equipment;

FIG. 18 is a third example diagram for explaining various arrangement structures of a plurality of process chambers in a semiconductor manufacturing equipment;

FIG. 19 is a fourth example diagram for explaining various arrangement structures of a plurality of process chambers in a semiconductor manufacturing equipment; and

FIG. 20 is a fifth example diagram for explaining various arrangement structures of a plurality of process chambers in a semiconductor manufacturing equipment.

### DETAILED DESCRIPTION

Hereinafter, embodiments of the present disclosure will be described in detail with reference to the attached drawings. The same reference numerals are used for the same components in the drawings, and duplicate descriptions thereof are omitted.

The present disclosure relates to a substrate processing apparatus applied to a photolithography process and a semiconductor manufacturing equipment including the same. The substrate processing apparatus of the present disclosure heat-treats a semiconductor substrate, and can process the semiconductor substrate using a laser. Hereinafter, the present disclosure will be described in detail with reference to the drawings.

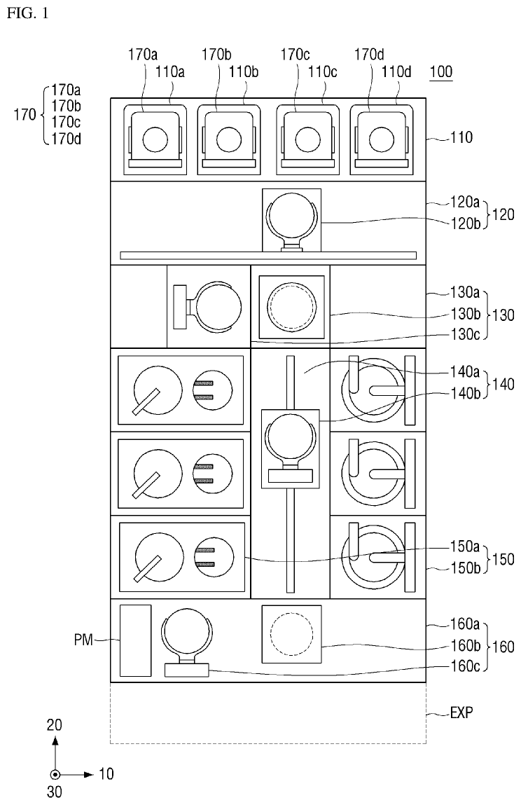

FIG. 1 is a first exemplary diagram schematically showing the internal structure of a semiconductor manufacturing equipment including a plurality of process chambers. According to FIG. 1, the semiconductor manufacturing equipment 100 may comprise a load port unit 110, an index module 120, a buffer module 130, a transfer module 140, a process chamber 150, and an interface module 160.

The semiconductor manufacturing equipment 100 is a system that processes semiconductor substrates through various processes such as a coating process, exposure process, development process, and heat treatment process. For this purpose, the semiconductor manufacturing equipment 100 may be provided as a multi-chamber type substrate processing system including a plurality of process chambers 150 of the same type or different types, such as a chamber for performing a photo resist coating process, a chamber for performing an exposure process, a chamber for performing a development process, and a chamber for performing a heat treatment process.

A load port unit 110 is provided so that the container 170 on which a plurality of semiconductor substrates is mounted can be seated. In the above, the container 170 may be, for example, a Front Opening Unified Pod (FOUP).

The container 170 may be loaded or unloaded in the load port unit 110. Additionally, the semiconductor substrate stored in the container 170 may be loaded or unloaded in the load port unit 110.

Although not shown in FIG. 1, in the former case, the container 170 may be loaded or unloaded into the load port unit 110 by a container transport device. Specifically, the container 170 can be loaded into the load port unit 110 by the container transport device seating the container 170 that has transported on the load port unit 110, and the container 170 can be unloaded from the load port unit 110 by the container transport device gripping the container 170 placed on the load port unit 110. In the above, the container transport device may be, for example, an overhead hoist transporter (OHT).

In the latter case, the semiconductor substrate may be loaded or unloaded from the container 170 seated on the load port unit 110 by the substrate transport robot 120b. When the container 170 is seated on the load port unit 110, the substrate transport robot 120b approaches the load port unit 110 and can then transport the semiconductor substrate from the container 170. Unloading of the semiconductor substrate can be accomplished through this process.

Additionally, when the processing of the semiconductor substrate is completed in the process chamber 150, the substrate transport robot 120b may remove the semiconductor substrate from the buffer module 130 and place it into the container 170. Loading of the semiconductor substrate can be accomplished through this process.

Additionally, when the processing of the semiconductor substrate is completed in the process chamber 150, the substrate transport robot 120b may remove the semiconductor substrate from the buffer module 130 and place it into the container 170. Loading of the semiconductor substrate can be accomplished through this process.

A plurality of load port units 110 may be arranged in front of the index module 120. For example, four load ports 110a, 110b, 110c, and 110d, including the first load port 110a, the second load port 110b, the third load port 110c, and the fourth load port 110d may be disposed in front of the index module 120.

When a plurality of load port units 110 are disposed in front of the index module 120, the containers 170 seated on each load port unit 110 can be equipped with different types of objects. For example, when four load port units 110 are disposed in front of the index module 120, the first pod 170a, which is seated on the first load port 110a on the left, can be equipped with a wafer-type sensor, the second pod 170b and the third pod 170c, which are seated on the second load port 110b and the third load port 110c in the center, can be equipped with a substrate (wafer), and the fourth pod 170d, which is seated on the fourth load port 110d on the right, can be equipped with consumable parts such as a focus ring and an edge ring.

However, this embodiment is not limited to this. The pods 170a, 170b, 170c, and 170d mounted on each load port 110a, 110b, 110c, and 110d can be equipped with objects of the same type. Alternatively, it is possible for pods seated on several load ports to be equipped with objects of the same type, and several other pods seated on different load ports to be equipped with objects of different types.

The index module 120 is disposed between the load port unit 110 and the buffer module 130, and serves as an interface to transfer the semiconductor substrate between the container 170 on the load port unit 110 and the buffer module 130. For this purpose, the index module 120 may include a substrate transport robot 120b in charge of transferring the substrate within the module housing 120a. At least one substrate transport robot 120b may be provided in the module housing 120a.

Although not shown in FIG. 1, at least one buffer chamber may be provided within the index module 120. In the buffer chamber, unprocessed substrates may be temporarily stored before being transferred to the buffer module 130, and processed substrates may be temporarily stored before being transported into the container 170 on the load port unit 110. The buffer chamber may be provided on a sidewall that is not adjacent to the load port unit 110 or the buffer module 130, but is not limited to this and may also be provided on a sidewall adjacent to the buffer module 130.

In this embodiment, a front end module (FEM) may be provided on one side of the buffer module 130. The front end module (FEM) may include a load port unit 110, an index module 120, etc., and may be provided as an Equipment Front End Module (EFEM), SFEM, etc.

Meanwhile, the plurality of load ports 110a, 110b, 110c, and 110d have a structure arranged in the horizontal direction (first direction 10) in the example of FIG. 1, but the present embodiment is not limited to this, and it is also possible to have a structure, in which a plurality of load ports 110a, 110b, 110c, and 110d are stacked in a vertical direction. In this case, the front end module can be provided, for example, as a vertically stacked EFEM.

The buffer module 130 functions as a buffer chamber between the input port and output port on the semiconductor manufacturing facility 100. The buffer module 130 may include a buffer stage 130b that temporarily stores a semiconductor substrate therein. The buffer stage 130b may be arranged in singular between the index module 120 and the transfer module 140, but is not limited to this and may be arranged in plural.

The buffer module 130 may include not only a buffer stage 130b but also a substrate transport robot 130c within the module housing 130a. When a plurality of buffer stages 130b are provided, the substrate transport robot 130c serves to transfer the substrate W between the plurality of buffer stages.

The buffer module 130 may have a semiconductor substrate loaded or unloaded by the substrate transport robot 140b of the transfer module 140. The buffer module 130 may have a semiconductor substrate loaded or unloaded by the substrate transport robot 120b of the index module 120.

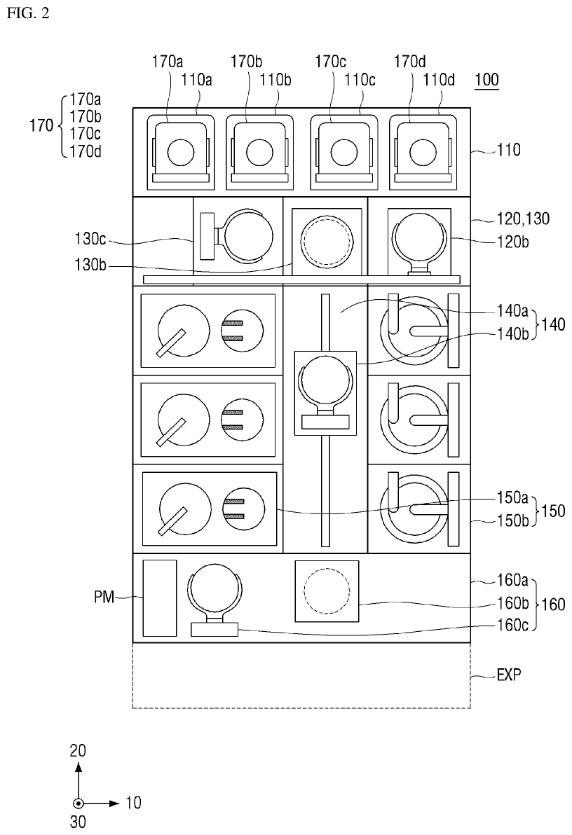

The buffer module 130 may be disposed behind the index module 120. That is, the buffer module 130 may not be arranged on the same line as the index module 120. However, this embodiment is not limited to this. The buffer module 130 may also be arranged on the same line as the index module 120, as shown in the example of FIG. 2. In this case, the substrate transport robot 120b of the index module 120, the substrate transport robot 130c of the buffer module 130, the buffer stage 130b, etc. may be disposed in a single module housing. FIG. 2 is a second exemplary diagram schematically showing the internal structure of a semiconductor manufacturing equipment including a plurality of process chambers.

Description will be made again with reference to FIG. 1.

The transfer module 140 serves as an interface so that the semiconductor substrate can be transferred between the buffer module 130 and the process chamber 150. For this purpose, the transfer module 140 may be equipped with a substrate transport robot 140b in charge of transferring the substrate within the module housing 140a. At least one substrate transport robot 140b may be provided in the module housing 140a.

The substrate transport robot 140b transfers an unprocessed substrate from the buffer module 130 to the process chamber 150 or transfers a processed substrate from the process chamber 150 to the buffer module 130. Each side of the transfer module 140 may be connected to the buffer module 130 and a plurality of process chambers 150 for this purpose. Meanwhile, the substrate transport robot 140b can be freely rotated.

The process chamber 150 serves to process the substrate. A plurality of process chambers 150 may be arranged around the transfer module 140. In this case, each process chamber 150 may receive a semiconductor substrate from the transfer module 140, process the semiconductor substrate, and provide the processed semiconductor substrate to the transfer module 140.

The process chamber 150 may be provided in a cylindrical or polygonal shape. This process chamber 150 may be made of alumite with an anodic oxide film formed on its surface, and its interior may be airtight. Meanwhile, the process chamber 150 may be formed in a shape other than a cylindrical shape or a polygonal shape in this embodiment.

The interface module 160 serves to transfer the substrate W. The interface module 160 may include a module housing 160a, a buffer stage 160b, and a substrate transport robot 160c. The buffer stage 160b and the substrate transport robot 160c are located within the module housing 160a. The buffer stage 160b may be provided in singular, but is not limited to this and may also be provided in plural. When a plurality of buffer stages 160b are provided, the plurality of buffer stages may be spaced a certain distance apart from each other and may be stacked on top of each other.

The substrate transport robot 160c serves to transport the substrate W between the buffer stage 160b and the exposure apparatus EXP. The buffer stage 160b temporarily stores the processed substrates W before they are moved to the exposure apparatus EXP. Alternatively, the buffer stage 160b temporarily stores the substrates W whose process has been completed in the exposure apparatus EXP before they are moved. The interface module 160 may be provided with only buffers and a robot as described above without providing a chamber for performing a predetermined process on a substrate.

Meanwhile, the purge module (PM) may be provided within the module housing 160a of the interface module 160. However, it is not limited to this, and the purge module (PM) may be provided at various locations, such as a location where the exposure device (EXP) is connected at the rear of the interface module 160, or the side of the interface module 160.

As previously described, the buffer stage 130b may be provided within the buffer module 130, and the buffer stage 160b may also be provided within the interface module 160. In this embodiment, the buffer stage 130b provided in the buffer module 130 is defined as the first buffer stage, the buffer stage 160b provided in the interface module 160 is defined as the second buffer stage, two buffer stages 130b and 160b are distinguished.

In addition, as described above, a substrate transport robot 120b may be provided in the index module 120, a substrate transport robot 130c may be provided in the buffer module 130, and a substrate transport robot 130c may be provided in the transfer module 140. In this embodiment, the substrate transfer robot 120b provided in the index module 120 is defined as the first transport robot, the substrate transport robot 130c provided in the buffer module 130 is defined as the second transport robot, the substrate transport robot 140b provided in the transfer module 140 is defined as the third transport robot, and the substrate transport robot 160c provided in the interface module 160 is defined as the fourth transport robot, and the four substrate transport robots 120b, 130c, 140b, and 160c are distinguished.

The semiconductor manufacturing equipment 100 can also be formed in a structure having an in-line platform as shown in FIG. 1. In this case, the plurality of process chambers 150 may be arranged in an in-line method with respect to the transfer module 140, and process chambers 150 of different types may form a corresponding relationship on both sides of the transfer module 140 and be arranged in series. However, it is not limited to this, and the semiconductor manufacturing equipment 100 may be formed in a structure having a cluster platform, or may be formed in a structure having a quad platform.

Next, the process chamber 150 provided within the semiconductor manufacturing equipment 100, that is, the substrate processing apparatus will be described. As described above, the semiconductor manufacturing equipment 100 may include a plurality of process chambers 150, and the plurality of process chambers 150 may be arranged in an in-line method with respect to the transfer module 140. In this case, different types of process chambers 150 may form a corresponding relationship and be arranged in a row on both sides of the transfer module 140. One type of process chamber 150 may be a substrate processing apparatus 150a that performs a heat treatment process on a substrate, and another type of process chamber 150 may be a substrate processing apparatus 150b that performs a development process on a substrate. Alternatively, another type of process chamber 150 may be a substrate processing apparatus 150b that performs a coating process on a substrate.

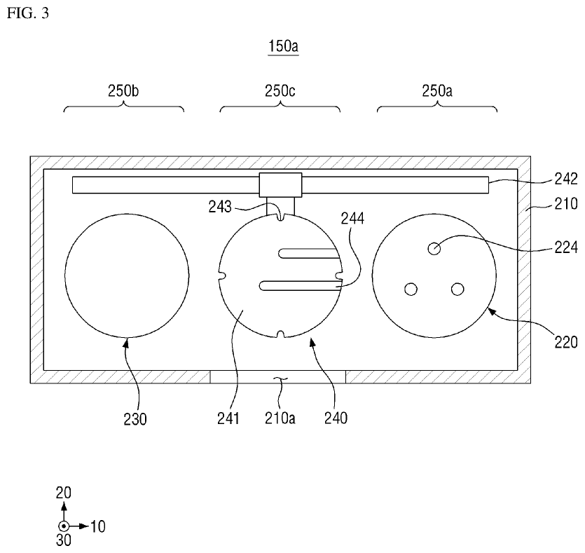

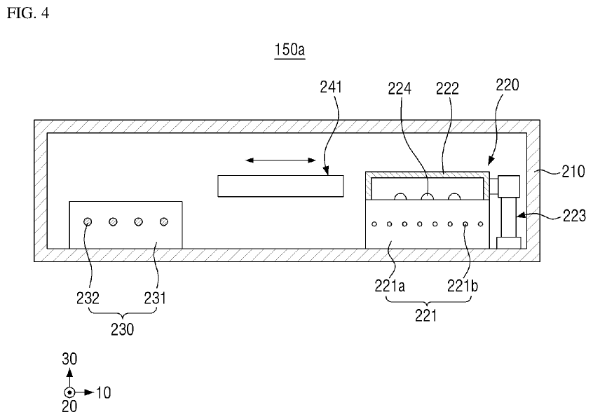

First, the substrate processing apparatus 150a that performs a heat treatment process on a substrate, that is, the first substrate processing apparatus 150a, will be described. FIG. 3 is a plan view schematically showing the internal structure of a substrate processing apparatus that performs a heat treatment process on a semiconductor substrate. FIG. 4 is a cross-sectional view schematically showing the internal structure of a substrate processing apparatus that performs a heat treatment process on a semiconductor substrate.

According to FIGS. 3 and 4, the substrate processing apparatus 150a may include a chamber housing 210, a heating unit 220, a cooling unit 230, and a transport unit 240.

The substrate processing apparatus 150a is an apparatus that heats and cools a substrate (e.g., wafer). This substrate processing apparatus 150a can heat and cool the substrate when performing a photo lithography process on the substrate. For example, the substrate processing apparatus 150a may be provided as a bake chamber that performs a bake process.

The photo lithography process may include a coating process, an exposure process, a development process, a bake process, etc. In this case, the substrate processing apparatus 150a may heat and/or cool the substrate before or after performing the coating process, that is, before or after applying photo resist (PR) on the substrate. Alternatively, the substrate processing apparatus 150a may heat and/or cool the substrate before or after performing the exposure process. Alternatively, the substrate processing apparatus 150a may heat and/or cool the substrate before or after performing the development process.

The chamber housing 210 provides a space for processing a substrate. The chamber housing 210 may be installed with a heating unit 220, a cooling unit 230, a transport unit 240, etc. therein to enable heating and cooling of the substrate.

An inlet 210a through which a substrate enters and exits may be formed on a side wall of the chamber housing 210. At least one inlet 210a may be provided in the chamber housing 210. The inlet 210a may always be open, and although not shown in FIG. 4, it also may be opened and closed through a door.

The internal space of the chamber housing 210 may be divided into a heating area 250a, a cooling area 250b, and a buffer area 250c. Here, the heating area 250a refers to an area where the heating unit 220 is placed, and the cooling area 250b refers to an area where the cooling unit 230 is placed. The heating area 250a may be provided the same as the width of the heating unit 220, or may be provided wider than the width of the heating unit 220. Likewise, the cooling area 250b may be provided the same as the width of the cooling unit 230 or may be provided wider than the width of the cooling unit 230.

The buffer area 250c refers to an area where the transport plate 241 of the transport unit 240 is disposed. The buffer area 250c may be provided between the heating area 250a and the cooling area 250b. When the buffer area 250c is provided in this way, the heating unit 220 and the cooling unit 230 can be sufficiently spaced apart to prevent thermal interference between them. As in the case of the heating area 250a and the cooling area 250b, the buffer area 250c may be provided the same as the width of the transport plate 241 or may be provided wider than the width of the transport plate 241.

When the heating unit 220, cooling unit 230, and transport unit 240 are respectively disposed on the heating area 250a, cooling area 250b, and buffer area 250c inside the chamber housing 210, the cooling unit 230, the transport unit 240, and the heating unit 220 may be arranged in the first direction 10 in that order. However, this embodiment is not limited to this. In this embodiment, it is also possible to arrange the heating unit 220, the transport unit 240, and the cooling unit 230 in the first direction 10 in that order.

The heating unit 220 heats the substrate. This heating unit 220 may provide gas on the substrate when heating the substrate. The heating unit 220 may provide, for example, hexamethyldisilane (Hexa-Methyl-Di-Silane) gas, and the supply of this gas can achieve the effect of improving the adhesion rate of the photoresist to the substrate.

The heating unit 220 may include a heating plate 221, a cover module 222, and a driving module 223 to heat the substrate.

The heating plate 221 is also called a hot plate and applies heat to the substrate. For this purpose, the heating plate 221 may include a body portion 221a and a heater 221b.

The body portion 221a supports the substrate when heat is applied to the substrate. This body portion 221a may be formed to have the same diameter as the substrate or may be formed to have a larger diameter than the substrate.

The body portion 221a may be manufactured from a metal with excellent heat resistance. Alternatively, the body portion 221a may be manufactured from a metal with excellent fire resistance. The body portion 221a may be manufactured using ceramics, such as aluminum oxide (Al2O3) and aluminum nitride (AIN).

Meanwhile, although not shown in FIGS. 3 and 4, the body portion 221a may be provided with a plurality of vacuum holes formed through the body portion 221a in the vertical direction (third direction 30). Here, the vacuum hole may serve to secure the substrate when heat is applied to the substrate by forming vacuum pressure.

Meanwhile, although not shown in FIGS. 3 and 4, the body portion 221a may be divided into an upper plate and a lower plate disposed below the upper plate. Here, the substrate may be seated on the upper plate, and the heater 221b may be installed inside the lower plate.

The heater 221b is used to apply heat to the substrate located on the body portion 221a. A plurality of such heaters 221b may be installed inside the body portion 221a. The heater 221b may be provided as a heating resistor (e.g., a heating wire) to which current is applied, but in this embodiment, it may be provided in a form other than a heating resistor as long as it can effectively apply heat to the substrate on the body portion 221a.

The cover module 222 is formed to cover the upper part of the heating plate 221 when the heating plate 221 heats the substrate. This cover module 222 can move in the vertical direction (third direction 30) under the control of the driving module 223 to open and close the upper part of the heating plate 221.

The driving module 223 moves the cover module 222 in the vertical direction (third direction 30). When the substrate is seated on the upper part of the heating plate 221 for heat treatment of the substrate, the driving module 223 may move a cover module 222 toward the bottom of the chamber housing 210 so that the cover module 222 can completely cover the upper part of the heating plate 221. In addition, when the heat treatment for the substrate is completed, the driving module 223 may move the cover module 222 toward the top of the chamber housing 210 to expose the upper part of the heating plate 221 so that the transport unit 240 can transfer the substrate to the cooling unit 230.

The cooling unit 230 cools the substrate heated by the heating unit 220. For this purpose, the cooling unit 230 may include a cooling plate 231 and a cooling member 232.

When high temperature heat is applied to the substrate through the heating unit 220, warpage may occur in the substrate. The cooling unit 230 may serve to restore the substrate to its original state by cooling the substrate heated by the heating unit 220 to an appropriate temperature.

The cooling member 232 is formed inside the cooling plate 231. This cooling member 232 may be provided in the form of a flow path through which cooling fluid flows.

The transport unit 240 moves the substrate to the heating unit 220 or the cooling unit 230. For this purpose, the transport unit 240 may have a hand coupled to the transport plate 241 at the end, and may move the transport plate 241 along the guide rail 242 in the direction where the heating unit 220 is located or in the direction where the cooling unit 230 is located.

The transport plate 241 has a disk shape and may be formed to have a diameter corresponding to the substrate. The transport plate 241 may include a plurality of notches 243 formed along the edge, and may include a plurality of guide grooves 244 having a slit shape on its upper surface.

The guide groove 244 may be formed to extend from an end of the transport plate 241 toward the center of the transport plate 241. At this time, the plurality of guide grooves 244 may be formed to be spaced apart from each other in the same direction (first direction 10). The guide groove 244 can prevent the transport plate 241 and the lift pin 224 from interfering with each other when the substrate is handed over between the transport plate 241 and the heating unit 220.

Heating of the substrate is performed when the substrate is placed directly on the heating plate 221, and cooling of the substrate is performed when the transport plate 241 on which the substrate is placed is in contact with the cooling plate 231. To ensure good heat transfer between the cooling plate 231 and the substrate, the transport plate 241 may be made of a material (for example, metal) with excellent heat transfer efficiency.

Meanwhile, although not shown in FIGS. 3 and 4, the transport unit 240 may receive a substrate from an externally installed substrate transport robot through the inlet 210a of the chamber housing 210.

The lift pin 224 has a free fall structure and serves to elevate the substrate on the heating plate 221. The lift pin 224 may be lowered on the heating plate 221 after receiving the substrate from the transport unit 240 in order to seat the substrate on the heating plate 221 when a bake process is performed on the substrate. Additionally, the lift pin 224 may be raised on the heating plate 221 to transfer the substrate to the transport unit 240 when the bake process for the substrate is completed. In order to perform this role, the lift pin 224 may be formed to penetrate the heating plate 221 in the vertical direction (third direction 30).

Like the case of the body portion 221a, the lift pin 224 may be made of a metal with excellent heat resistance or may be made of a metal with excellent fire resistance. In this case, the lift pin 224 may be manufactured from the same metal as the body portion 221a, but may also be manufactured from different metals.

The lift pin 224 may be operated using, for example, an LM guide system (Linear Motor guide system) and may be controlled by a plurality of cylinders connected to the LM guide system. The LM guide system has the advantage of being able to respond to high temperatures and high vibrations.

Meanwhile, a plurality of lift pins 224 may be installed to stably support the substrate when elevating the substrate on the heating plate 221. For example, three lift pins 224 may be installed as shown in FIGS. 3 and 4.

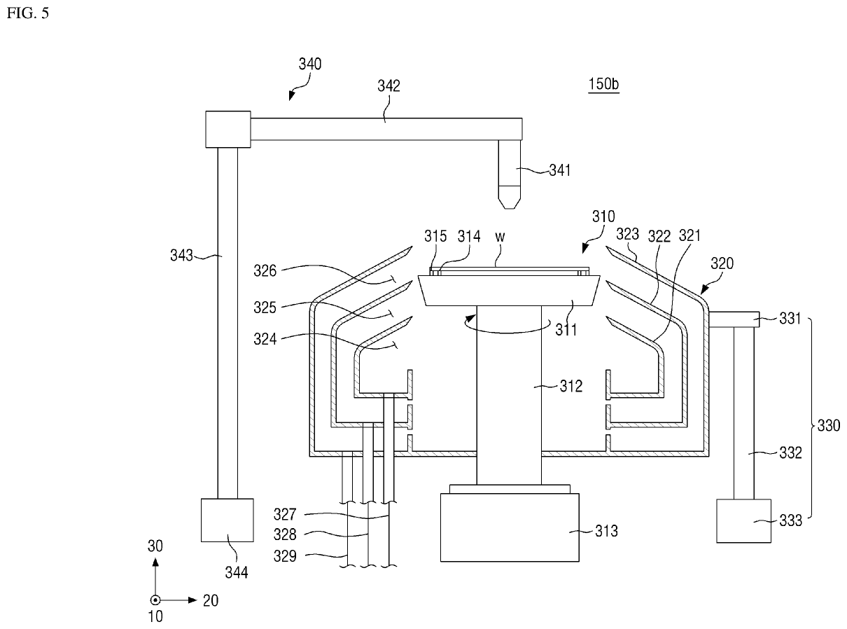

Next, the substrate processing apparatus 150b that performs a development process on a substrate, that is, the second substrate processing apparatus 150b, will be described. FIG. 5 is a cross-sectional view schematically showing the internal structure of a substrate processing apparatus that performs a development process on a semiconductor substrate.

The substrate processing apparatus 150b is an apparatus that processes a substrate using a chemical liquid. When performing a development process, the substrate processing apparatus 150b can remove photoresist from the substrate using a chemical liquid. The substrate processing apparatus 150b may be provided as a cleaning process chamber that cleans the substrate using a chemical liquid.

The substrate processing apparatus 150b can also be provided as an apparatus that performs a coating process on a semiconductor substrate. In this case, the substrate processing apparatus 150b can form a photoresist on the substrate using a chemical liquid.

The chemical liquid may be a substance in a liquid state (for example, an organic solvent) or a substance in a gaseous state. Chemical liquids are highly volatile and may contain substances that generate a lot of fume or have high viscosity and thus high residual properties. Chemical liquids can be selected from, for example, a material containing IPA (Iso-Propyl Alcohol) component, a material containing sulfuric acid (e.g., SPM containing sulfuric acid and hydrogen peroxide) component, a material containing ammonia water component (e.g., SC-1 (H₂O₂+NH₄OH), a material containing a hydrofluoric acid component (e.g., DHF (Diluted Hydrogen Fluoride)), a material containing a phosphoric acid component, etc. Hereinafter, these chemical liquids used in processing a substrate will be defined as substrate processing liquids.

When applied to a cleaning process as described above, the substrate processing apparatus 150b may rotate the substrate using a spin head and provide a chemical liquid on the substrate using a nozzle. When the substrate processing apparatus 150b is provided as a liquid processing chamber in this way, as shown in FIG. 5, it may comprise a substrate support unit 310, a processing liquid recovery unit 320, an elevation unit 330, and a spray unit 340.

The substrate support unit 310 is a module that supports the substrate W. When processing the substrate W, the substrate support unit 310 may rotate the substrate W in a direction perpendicular to the third direction 30 (first direction 10 and second direction 20). The substrate support unit 310 may be disposed inside the processing liquid recovery unit 320 to recover the substrate processing liquid used when processing the substrate W.

The substrate support unit 310 may comprise a spin head 311, a rotation shaft 312, a rotation driving module 313, a support pin 314, and a guide pin 315.

The spin head 311 rotates along the rotation direction of the rotation shaft 312 (perpendicular to the third direction 30). This spin head 311 may be provided to have the same shape as the substrate W. However, this embodiment is not limited to this. The spin head 311 may be provided to have a shape different from that of the substrate W.

The rotation shaft 312 generates rotation force using energy provided from the rotation driving module 313. This rotation shaft 312 is coupled to the rotation driving module 313 and the spin head 311, respectively, and can transmit the rotation force generated by the rotation driving module 313 to the spin head 311. The spin head 311 rotates along the rotation shaft 312, and in this case, the substrate W seated on the spin head 311 may also rotate together with the spin head 311.

The support pin 314 and guide pin 315 fix the position of the substrate W on the spin head 311. For this purpose, the support pin 314 supports the bottom of the substrate W on the spin head 311, and the guide pin 315 supports the side of the substrate W. A plurality of support pins 314 and guide pins 315 may be installed on the spin head 311, respectively.

The support pin 314 may be arranged to have an overall annular ring shape. The support pin 314 can support the bottom of the substrate W so that the substrate W can be spaced a certain distance away from the top of the spin head 311.

The guide pin 315 is a chucking pin and can support the substrate W so that the substrate W does not deviate from its original position when the spin head 311 rotates.

The processing liquid recovery unit 320 recovers the substrate processing liquid used to process the substrate W. The processing liquid recovery unit 320 may be installed to surround the substrate support unit 310, thereby providing a space where a processing process for the substrate W is performed.

After the substrate W is seated and fixed on the substrate support unit 310 and starts to rotate by the substrate support unit 310, the spray unit 340 may spray the substrate processing liquid on the substrate W under the control of the control unit. Then, the substrate processing liquid discharged on the substrate W may be dispersed in the direction where the processing liquid recovery unit 320 is located due to the centrifugal force generated by the rotation force of the substrate support unit 310. In this case, when the substrate processing liquid flows through the inlet (i.e., the first opening unit 324 of the first recovery container 321, the second opening unit 325 of the second recovery container 322, and third opening unit 326 of the third recovery container, which will be described later) into the inside, the processing liquid recovery unit 320 can recover the substrate processing liquid. The control unit will be described later.

The processing liquid recovery unit 320 may be configured to include a plurality of recovery containers. The processing liquid recovery unit 320 may be configured to include, for example, three recovery containers. When the processing liquid recovery unit 320 is configured to include a plurality of recovery containers as described above, the substrate processing liquid used in the substrate processing process can be separated and recovered using the plurality of recovery containers, and accordingly recycling of the substrate processing liquid may become possible.

When the processing liquid recovery unit 320 is configured to include three recovery containers, it may include a first recovery container 321, a second recovery container 322, and a third recovery container 323. The first recovery container 321, the second recovery container 322, and the third recovery container 323 may be implemented as a bowl, for example.

The first recovery container 321, the second recovery container 322, and the third recovery container 323 may recover different substrate processing liquids. For example, the first recovery container 321 can recover a rinse solution (e.g., DI Water (Deionized Water)), the second recovery container 322 can recover the first chemical liquid, and the third recovery container 323 can recover the second chemical liquid.

The first recovery container 321, the second recovery container 322, and the third recovery container 323 may be connected to recovery lines 327, 328, and 329 extending from their bottoms in a downward direction (third direction 30). The first processing liquid, second processing liquid, and third processing liquid recovered through the first recovery container 321, the second recovery container 322, and the third recovery container 323 can be processed for reuse in a processing liquid regeneration system (not shown).

The first recovery container 321, the second recovery container 322, and the third recovery container 323 may be provided in an annular ring shape surrounding the substrate support unit 310. The size of the first recovery container 321, the second recovery container 322, and the third recovery container 323 may increase, as it moves from the first recovery container 321 to the third recovery container 323 (i.e., in the second direction 20). The gap between the first recovery container 321 and the second recovery container 322 is defined as the first gap, and the gap between the second recovery container 322 and the third recovery container 323 is defined as the second gap. Then, the first gap may be equal to the second gap. However, this embodiment is not limited to this. It is also possible that the first gap is different from the second gap. That is, the first gap may be larger than the second gap, or may be smaller than the second gap.

The elevation unit 330 moves the processing liquid recovery unit 320 in a straight line in the vertical direction (third direction 30). The elevation unit 330 may serve to adjust the relative height of the processing liquid recovery unit 320 with respect to the substrate support unit 310 (or substrate W).

The elevation unit 330 may be configured to include a bracket 331, a first support shaft 332, and a first driving module 333.

The bracket 331 is fixed to the outer wall of the processing liquid recovery unit 320. The bracket 331 may be coupled to the first support shaft 332 moved in the vertical direction by the first driving module 333.

When seating the substrate W on the substrate support unit 310, the substrate support unit 310 may be located higher than the processing liquid recovery unit 320. Likewise, even when detaching the substrate W from the substrate support unit 310, the substrate support unit 310 may be located higher than the processing liquid recovery unit 320. In the above case, the elevation unit 330 may serve to lower the processing liquid recovery unit 320.

When a processing process for the substrate W is in progress, the processing liquid can be recovered into any one of the first recovery container 321, the second recovery container 322, and the third recovery container 323 depending on the type of substrate processing liquid discharged on the substrate W. Even in this case, the elevation unit 330 may serve to raise and lower the processing liquid recovery unit 320 to the corresponding position. For example, when using the first processing liquid as the substrate processing liquid, the elevation unit 330 can raise and lower the processing liquid recovery unit 320 so that the substrate W is located at a height corresponding to the first opening unit 324 of the first recovery container 321.

Meanwhile, in this embodiment, the elevation unit 330 may also move the substrate support unit 310 in straight line in the vertical direction to adjust the relative height of the processing liquid recovery unit 320 with respect to the substrate support unit 310 (or substrate W).

However, this embodiment is not limited to this. The elevation unit 330 simultaneously may also move the substrate support unit 310 and the processing liquid recovery unit 320 in the vertical direction to adjust the relative height of the processing liquid recovery unit 320 relative to the substrate support unit 310 (or the substrate W).

The spray unit 340 is a module that supplies substrate processing liquid onto the substrate W when processing the substrate W. At least one such spray unit 340 may be installed in the substrate processing apparatus 150b. When a plurality of spray units 340 are installed in the substrate processing apparatus 150b, each spray unit 340 may spray different substrate processing liquids on the substrate W.

The spray unit 340 may include a nozzle structure 341, a nozzle support module 342, a second support shaft 343, and a second driving module 344.

The nozzle structure 341 is installed at the end of the nozzle support module 342. This nozzle structure 341 can be moved to a process position or a standby position by the second driving module 344.

In the above, the process position refers to the upper area of the substrate W, and the standby position refers to the remaining area excluding the process position. The nozzle structure 341 may be moved to the process position when discharging the substrate processing liquid on the substrate W, and after discharging the substrate processing liquid on the substrate W, it may leave the process position and move to the standby position.

The nozzle support module 342 supports the nozzle structure 341. This nozzle support module 342 may be formed to extend in a direction corresponding to the longitudinal direction of the spin head 311. That is, the nozzle support module 342 may be provided so that its longitudinal direction is along the second direction 20.

The nozzle support module 342 may be coupled to a second support shaft 343 extending in a direction perpendicular to the longitudinal direction. The second support shaft 343 may extend in a direction corresponding to the height direction of the spin head 311. That is, the second support shaft 343 may be provided so that its longitudinal direction is along the third direction 30.

The second driving module 344 is a module that rotates and elevates the second support shaft 343 and the nozzle support module 342 interworked to the second support shaft 343. Depending on this function of the second driving module 344, the nozzle structure 341 can be moved to a process position or a standby position.

Although not shown in FIG. 5, the substrate processing apparatus 150b may further include a substrate processing liquid providing module. The substrate processing liquid providing module serves to provide substrate processing liquid within the substrate processing apparatus 150b. The substrate processing liquid providing module may be connected to the spray unit 340 for this purpose and may operate under the control of the control unit.

Although not shown in FIGS. 1 to 5, the semiconductor manufacturing equipment 100 may further include a control unit.

The control unit serves to control the overall operation of each unit constituting the semiconductor manufacturing equipment 100. For example, the control unit may control the loading and unloading of substrates of the substrate transport robot 120b of the index module 120, the substrate transport robot 130c of the buffer module 130, and the substrate transport robot 140b of the transfer module 140, and may control the substrate processing process of the process chamber 150. Additionally, the control unit may control the operation of the substrate processing liquid providing module and may also control the operation of each unit provided in the process chamber 150.

The control unit may comprise a process controller consisting of a microprocessor (computer) that controls the semiconductor manufacturing equipment 100, a user interface consisting of a keyboard that allow an operator to perform a command input manipulations to manage the semiconductor manufacturing equipment 100 and a display that visualizes and displays the operating status of the semiconductor manufacturing equipment 100, a control program for executing the processing performed in the semiconductor manufacturing equipment 100 under the control of the process controller, and a memory unit, in which a program for executing processing according to various data and processing conditions in each component, that is, a processing recipe, is stored. Additionally, the user interface and memory unit may be connected to the process controller. The processing recipe may be stored in a memory medium in the memory unit, and the memory medium may be a hard disk, a portable disk such as a CD-ROM or DVD, or a semiconductor memory such as a flash memory.

As described above, when the heating unit 220 in the substrate processing apparatus 150a, that is, the first substrate processing apparatus 150a, which performs a heat treatment process on the semiconductor substrate W is provided in the hot plate type, due to the convection phenomenon according to the temperature difference within the chamber, non-uniformity may occur in the surface temperature of each region of the semiconductor substrate W, which may cause thickness deviation in the fine pattern and reduce process yield. To solve this problem, the heating unit 220 of the present disclosure may include a laser signal generation module and can process the semiconductor substrate W using a laser signal generated by the laser signal generation module. This is explained below.

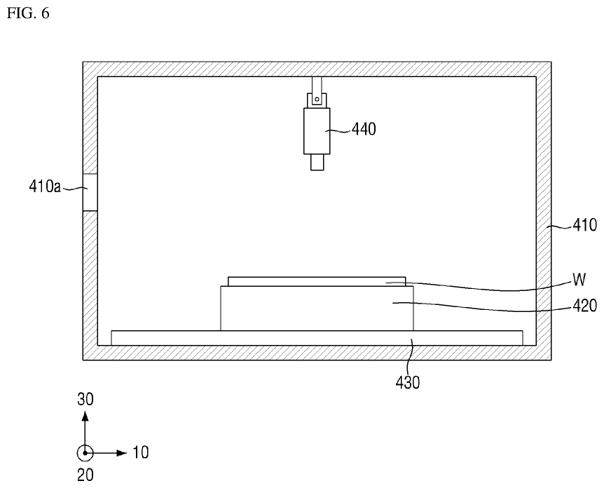

FIG. 6 is a diagram schematically showing the internal structure of a heating unit in a first substrate processing apparatus including a laser signal generation module. According to FIG. 6, the heating unit 220 may include a chamber 410, a support module 420, a stage 430, and a laser signal generation module 440.

The heating unit 220 including the laser signal generation module 440, that is, the substrate processing apparatus using a laser is a bake processing device that heats the semiconductor substrate W using a laser capable of rapid heat treatment, in which temperature uniformity is important as the pattern line width is refined. The heating unit 220 including the laser signal generation module 440 can incident a laser signal to heat a specific layer (a thin film containing a metal component or a metal thin film) even when multiple layers are deposited. It may be configured as a laser system capable of scanning the entire surface of the semiconductor substrate W or a portion thereof.

The chamber 410 provides a space where the semiconductor substrate W is processed. The chamber 410 may be provided as a closed structure including a window 410a on the side wall through which the semiconductor substrate W can enter and exit, but is not limited thereto, and it is also possible to provide a structure, in which the upper part is open and closed including the cover module 222 and the driving module 223 of FIG. 4.

The support module 420 is disposed inside the chamber 410 and serves to support the semiconductor substrate W while the semiconductor substrate W is being processed. The support module 420 may have a plate structure and may have a structure to adsorb the semiconductor substrate W so that its position is fixed while the semiconductor substrate W is being processed.

The support module 420 may be provided with the same material as the body portion 221a of FIG. 4. In this case, the support module 420 may not include a heater therein. However, it is not limited to this, and the support module 420 may be provided with a heating module therein, such as the heating plate 221 of FIG. 4 including a body portion 221a and a heater 221b. When the support module 420 is provided in a structure including a heating module, it may be possible to process the semiconductor substrate W more efficiently through interaction with the laser signal generation module 440.

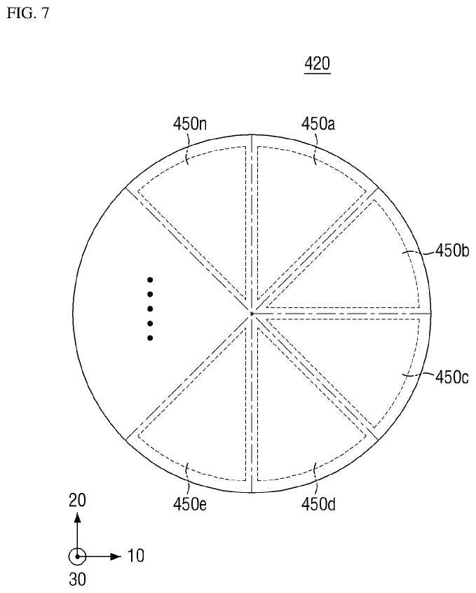

For example, when the semiconductor substrate W is divided into a plurality of areas, the laser signal generation module 440 may perform heat treatment on some areas among the plurality of areas. In this case, if heat treatment is required for the remaining areas except for the some areas, heat treatment can be performed on the corresponding areas using a heating module installed in the support module 420. Taking this aspect into consideration, the heating module installed in the support module 420 may be composed of a plurality of heating modules 450a, 450b, . . . , 450n, as shown in the example of FIG. 7, and the plurality of heating modules 450a, 450b, . . . , 450n may serve to partially heat each area of the semiconductor substrate W. FIG. 7 is an example diagram for explaining the heating module within the plate constituting the heating unit.

Meanwhile, if heat treatment is required for some of the plurality of areas, the laser signal generation module 440 may perform heat treatment on the corresponding areas, and if the laser signal generation module 440 cannot perform heat treatment on all of the areas, the laser signal generation module 440 and the heating modules 450a, 450b, . . . , 450n may divide the corresponding areas and perform heat treatment.

This will be described again with reference to FIG. 6.

The stage 430 may be provided below the support module 420. The stage 430 may serve to freely move the support module 420 within the chamber 410. When the support module 420 is fixed within the chamber 410, it is possible even if the stage 430 is not provided within the heating unit 220.

The laser signal generation module 440 generates a laser signal and transmits the laser signal onto the semiconductor substrate W. The laser signal generation module 440 may partially heat-treat the semiconductor substrate W using a laser signal, but is not limited to this, and may heat-treat the entire semiconductor substrate W at the same time.

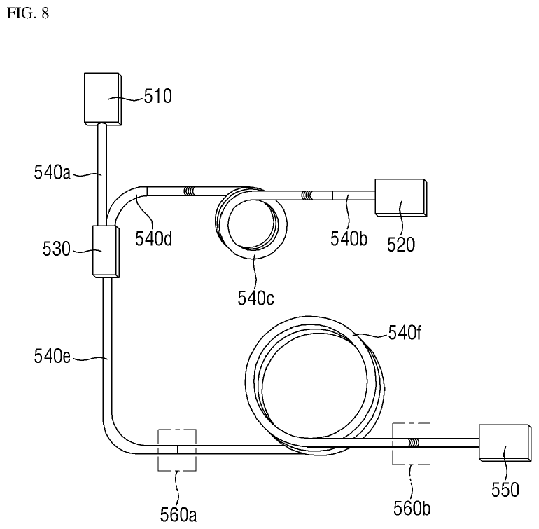

The laser signal generation module 440 may comprise a first laser diode 510, a second laser diode 520, a pump combiner 530, an external transmission part 550, a first optical fiber 540a, a second optical fiber 540b, a third optical fiber 540c, a fourth optical fiber 540d, a fifth optical fiber 540e, and a sixth optical fiber 540f as shown in the example of FIG. 8 to process the semiconductor substrate W. FIG. 8 is an example diagram for explaining the internal structure of the laser signal generation module constituting the heating unit.

The first laser diode 510 and the second laser diode 520 function as laser diodes that generate and output laser signals. The first laser diode 510 and the second laser diode 520 may generate and output laser signals of different wavelengths. For example, the first laser diode 510 can generate and output a laser signal with a wavelength of 974 nm, and the second laser diode 520 can generate and output a laser signal with a wavelength of 791 nm.

The laser signal generation module 440 may be configured to include two laser diodes 510 and 520, but is not limited to this and can also be configured to include a single laser diode. Alternatively, the laser signal generation module 440 may be configured to include three or more laser diodes.

The pump combiner 530 serves to combine the first laser signal generated and output by the first laser diode 510 and the second laser signal generated and output by the second laser diode 520. For this purpose, the pump combiner 530 may be connected to the first laser diode 510 and the second laser diode 520, respectively.

The external transmission part 550 serves to transmit to the outside the laser signal combined by the pump combiner 530, that is, the combined laser signal obtained by combining the first laser signal and the second laser signal. For example, the external transmission part 550 can transmit a laser signal with a wavelength of 3.44 μm to the outside. In this embodiment, the laser signal transmitted by the external transmission part 550 can be used to process the semiconductor substrate W.

The first optical fiber 540a may connect the first laser diode 510 and the pump combiner 530. The first optical fiber 540a may be made of silicon dioxide (SiO₂) and may be formed as a multi-mode fiber with a certain diameter. For example, it may be composed of 105/125 μm SiO₂ Fiber.

The optical fiber connecting the first laser diode 510 and the pump combiner 530 may be composed of a single optical fiber, but is not limited to this, and it is also possible to be composed of a plurality of optical fibers, as in the case of optical fibers (second optical fiber 540b, third optical fiber 540c, and fourth optical fiber 540d) connecting the second laser diode 520 and the pump combiner 530.

The second optical fiber 540b, third optical fiber 540c, and fourth optical fiber 540d may connect the second laser diode 520 and the pump combiner 530. The second optical fiber 540b may connect the second laser diode 520 and the third optical fiber 540c, and the third optical fiber 540c may connect the second optical fiber 540b and the fourth optical fiber 540d, and the fourth optical fiber 540d may connect the third optical fiber 540c and the pump combiner 530.

The second optical fiber 540b, third optical fiber 540c, and fourth optical fiber 540d may be formed of multi-mode fibers containing the same material and having different diameters. For example, the second optical fiber 540b, third optical fiber 540c, and fourth optical fiber 540d may be formed as multi-mode fibers using SiO₂ material.

Some of the second optical fiber 540b, third optical fiber 540c, and fourth optical fiber 540d may have the same shape, and others may have different shapes. For example, the second optical fiber 540b may have a core structure, and the third optical fiber 540c and the fourth optical fiber 540d may have a cladding structure. Here, an optical fiber with a core structure refers to an optical fiber made of very thin glass or plastic, and an optical fiber with a cladding structure refers to a Kevlar fiber that is used to withstand strong forces around the glass fiber. However, it is not limited to this, and the second optical fiber 540b, third optical fiber 540c, and fourth optical fiber 540d may all have the same shape. Alternatively, the second optical fiber 540b, third optical fiber 540c, and fourth optical fiber 540d may all have different shapes.

As described above, the second optical fiber 540b, third optical fiber 540c, and fourth optical fiber 540d may have different diameters, and some may have different shapes from others. For example, the second optical fiber 540b may be composed of 105/125 μm SiO₂ fiber, the third optical fiber 540c may be composed of 11/240*260 μm Tm³⁺:SiO₂ Double-clad fiber, and the fourth optical fiber 540d may be composed of 11/250 μm SiO₂ Double-clad fiber.

The optical fiber connecting the second laser diode 520 and the pump combiner 530 may be composed of a plurality of optical fibers, but is not limited thereto, and it is also possible to be composed of a single optical fiber, as in the case of an optical fiber (the first optical fiber 540a) connecting the first laser diode 510 and the pump combiner 530.

The fifth optical fiber 540e and the sixth optical fiber 540f may connect the pump combiner 530 and the external transmission part 550. The fifth optical fiber 540e may connect the pump combiner 530 and the sixth optical fiber 540f, and the sixth optical fiber 540f may connect the fifth optical fiber 540e and the external transmission part 550.

The fifth optical fiber 540e and the sixth optical fiber 540f may be formed as multi-mode fibers containing different components and having different diameters. For example, the fifth optical fiber 540e may be formed as a multi-mode fiber including SiO₂ material, and the sixth optical fiber 540f may be formed as a multi-mode fiber including other materials.

The fifth optical fiber 540e and the sixth optical fiber 540f may have the same shape. For example, the fifth optical fiber 540e and the sixth optical fiber 540f may have a cladding structure. However, it is not limited to this, and the fifth optical fiber 540e and the sixth optical fiber 540f may have different shapes.

As described above, the fifth optical fiber 540e and the sixth optical fiber 540f may have different diameters and the same shape. For example, the fifth optical fiber 540e may be composed of 11/250 μm SiO₂ double-clad fiber, and the sixth optical fiber 540f may be composed of 16.5/240*260 82 m Er³⁺:FG double-clad fiber.

The optical fiber connecting the pump combiner 530 and the external transmission part 550 may be composed of a plurality of optical fibers, but is not limited to this, and it is also possible to be composed of a single optical fiber, as in the case of an optical fiber (first optical fiber 540a) connecting the first laser diode 510 and the pump combiner 530.

Meanwhile, RPS may be generated at the ending portion of the third optical fiber 540c, that is, the portion connected to the fourth optical fiber 540d. Alternatively, RPS may be generated at the beginning portion of the fourth optical fiber 540d connected to the ending portion of the third optical fiber 540c. Additionally, RPS may be generated at the ending portion of the sixth optical fiber 540f, that is, at the portion connected to the external transmission part 550.

Meanwhile, the third optical fiber 540c and the sixth optical fiber 540f can each satisfy the following conditions.
Third optical fiber 540c: Tm³⁺:SiO₂ Cavity 1976 nm
Sixth optical fiber 540f: Er³⁺:FG Cavity L=4.3 m

In addition, the connection part 560a between the fifth optical fiber 540e and the sixth optical fiber 540f and the Bragg grating part 560b within the sixth optical fiber 540f may each satisfy the following conditions.
Connection part 560a between the fifth optical fiber 540e and the sixth optical fiber 540f: HR-DM R≈96%, Butt-Coupled Alignment
Bragg grating part 560b in the sixth optical fiber 540f: LR-FBG (Fiber Bragg Grating) R≈55%, 7° Angle Cleave

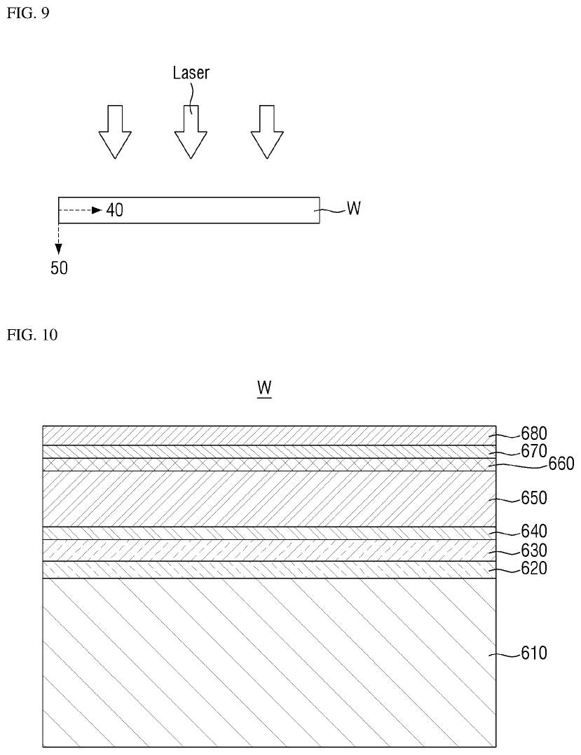

The laser signal generation module 440 may be composed of a laser source and a precision control stage as shown in the example of FIG. 8, and when transmitting a laser signal on the semiconductor substrate W, as shown in the example of FIG. 9, a laser signal may be incident on the semiconductor substrate W in a vertical direction. That is, the incident direction of the laser signal may be parallel to the thickness direction 50 of the semiconductor substrate W and perpendicular to the width direction 40 of the semiconductor substrate W. FIG. 9 is a first example diagram for explaining the performance of the laser signal generation module constituting the heating unit.

The laser signal generation module 440 may incident a laser signal on the semiconductor substrate W in a diagonal direction. In this case, the laser signal generation module 440 can perform annealing by applying heat to the metal layer in the semiconductor substrate W with a laser signal incident in a diagonal direction. However, if there is no thin film containing a metal component in the semiconductor substrate W, there may be difficulties in heating the film.

The semiconductor substrate W brought into the heating unit 220 for heat treatment may have a hierarchical structure as shown in the example of FIG. 10. For example, the semiconductor substrate W may comprise a substrate layer 610, a dielectric layer 620, a first hardmask layer 630, a second hardmask layer 640, an SOH layer 650, a SiON layer 660, an under layer 670, and a photoresist layer 680. FIG. 10 is an example diagram for explaining the internal structure of a semiconductor substrate heat treated by a laser signal generation module.

The substrate layer 610 may be made of silicon (Si) as the lowest layer. The dielectric layer 620 may be formed on substrate layer 610. The dielectric layer 620 may be composed of a SiOCN material and may be provided as a BEOL dielectric layer, for example.

The first hardmask layer 630 may be formed on the dielectric layer 620. The first hardmask layer 630 may include TiN material and may be provided as a metal hardmask. The second hardmask layer 640 may be formed on the first hardmask layer 630. The second hardmask layer 640 may include a SiON material and may be provided as a hardmask.

A SOH layer 650 may be formed on the second hardmask layer 640, a SiON layer 660 may be formed on the SOH layer 650, and an under layer 670 may be formed on the SiON layer 660, and a photoresist layer 680 may be formed on the under layer 670.

In this embodiment, the laser signal generation module 440 may incident a laser signal on the semiconductor substrate W in a vertical direction. The laser signal generation module 440 can heat the first hardmask layer 630, SOH layer 650, under layer 670, and photoresist layer 680, and the heating unit 220 including the laser signal generation module 440 can achieve the effect of enabling film heating even if the semiconductor substrate W does not include a metal layer.

The laser signal generation module 440 may incident a laser signal of a specific wavelength on the semiconductor substrate W so that only a specific layer in the semiconductor substrate W (e.g., the first hardmask layer 630, the SOH layer 650, the under layer 670, the photoresist layer 680, etc.) is heated for PEB (Poset Exposure Bake). For example, the laser signal generation module 440 may incident a Mid-IR laser. The laser signal generation module 440 can selectively heat a thin film containing a polymer component using a Mid-IR laser. For example, the laser signal generation module 440 can selectively heat the PR film, SOH film, anti-reflection film, etc.

As explained previously, if a thin film containing a metal component is not deposited in the semiconductor substrate W, when a laser signal is incident on the semiconductor substrate W in an oblique direction, it is difficult to heat the PR thin film. In this embodiment, the laser signal generation module 440 may cause a laser signal to be incident on the semiconductor substrate W in a vertical direction, and may cause a laser signal of a specific wavelength to be incident on the semiconductor substrate W. In this embodiment, it is possible to directly heat only thin films containing polymer components such as PR film, under layer, and SOH film through heat absorption that occurs when a laser of a specific wavelength that reacts only to polymer chemical structures such as C—H bonds is incident.

In the above, the laser signal generated and output by the laser signal generation module 440 may be a Mid-IR laser signal. The laser signal generated and output by the laser signal generation module 440 may be a laser signal having a wavelength of 3 μm to 50 μm.

The laser signal generation module 440 uses a laser signal with a wavelength in the Mid-IR band, that is, a laser signal with a wavelength of 3 μm to 50 μm, so that, as shown in the example of FIG. 10, even if the semiconductor substrate W has a structure in which a multilayer thin film is deposited, only the thin film containing a polymer component can be selectively heated. That is, the heating unit 220 including the laser signal generation module 440 can achieve an effect of heating the film even if the semiconductor substrate W does not include a metal layer (for example, the first hardmask layer 630 in FIG. 10). In addition, the heating unit 220 including the laser signal generation module 440 can achieve the effect of direct baking as long as the semiconductor substrate W contains only a thin film containing a polymer even if the semiconductor substrate W contains a metal layer.

When the laser signal generation module 440 uses a laser signal having a wavelength in the Mid-IR band (i.e., a wavelength of 3 μm to 50 μm), the heating unit 220 including the laser signal generation module 440, that is, a substrate processing apparatus using a laser can be provided as a Mid-IR Laser PR Bake. In this case, the substrate processing apparatus may have the following performance.

The substrate processing apparatus is capable of heating only specific layers, such as metal and polymer, by incident a mid-IR wavelength laser signal onto the semiconductor substrate W. In addition, the substrate processing apparatus is capable of directly heating the target PR thin film through vibration, translation, rotation, etc. of the polymer molecule bonding structure present in the target PR thin film. In addition, the substrate processing apparatus can selectively heat only the target polymer thin film without damaging the underlying substrate even when the semiconductor substrate W has a structure in which a multilayer thin film is deposited. In addition, the substrate processing apparatus can directly heat the target PR thin film even if it is a NON-CAR type as long as the target PR thin film contains polymer or metal as a component.

The laser signal generation module 440 may utilize an optical fiber laser containing a fluorine component, that is, a fluoride fiber laser, as a light source. Alternatively, the laser signal generation module 440 may utilize a CO2 laser as a light source.

The laser signal generation module 440 can satisfy the following conditions when using a fluoride fiber laser as a light source.
λ≈3.44 μm
Power: Low
Size: Small
Energy Absorption at PR (Polymer): Big
PR has high energy absorption rate, enabling self-heating→can be applied universally

The laser signal generation module 440 can satisfy the following conditions when using a CO2 laser as a light source.
λ≈10.6 μm
Power: High
Size: Big
Energy Absorption at PR (Polymer): Small
PR's own energy absorption rate is low, but its laser power is high, enabling self-heating.

The heating unit 220 including the laser signal generation module 440, that is, a substrate processing apparatus using a laser, may be provided as a laser annealing bake for an annealing process for the semiconductor substrate W. The substrate processing apparatus can operate by applying a high temperature in a short time, and the part hit by the laser beam is heat treated to a high temperature in a short time, but the temperature of the part where the laser passes can be immediately cooled.

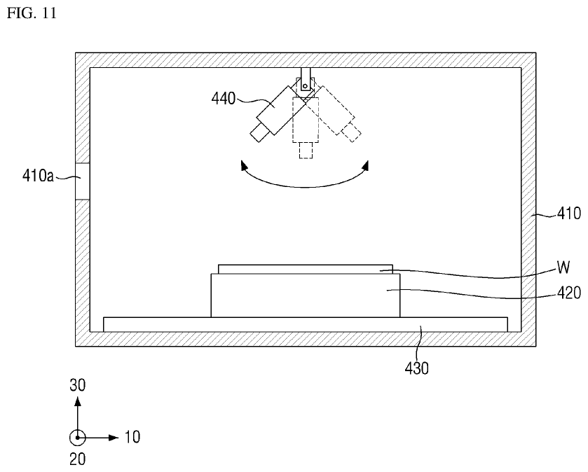

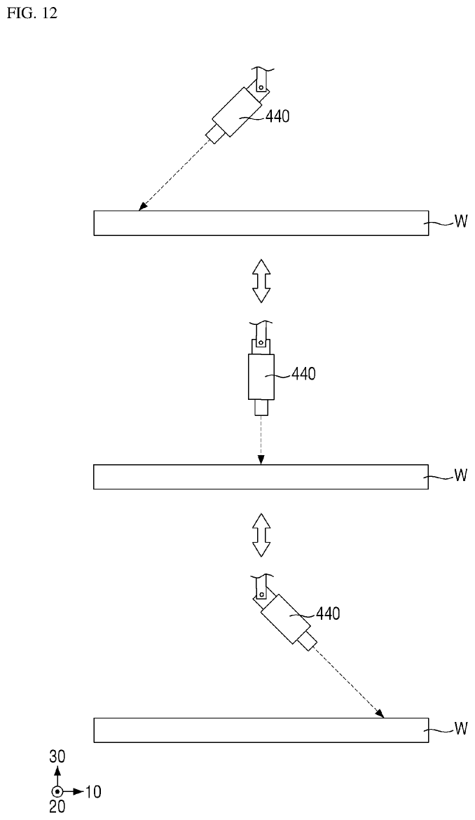

The laser signal generation module 440 may be provided to be rotatable as shown in the example of FIG. 11. That is, the laser emission angle of the laser signal generation module 440 can be varied. Through this operation, the laser signal generation module 440 can heat a desired area on the semiconductor substrate W, as shown in the example of FIG. 12.

The laser emission angle of the laser signal generation module 440 may vary depending on the results of the camera module's photographing of the semiconductor substrate W. Although not shown in FIGS. 11 and 12, the camera module may be arranged parallel to the laser signal generation module 440 on the ceiling of the chamber 410. FIG. 11 is a second example diagram for explaining the performance of the laser signal generation module constituting the heating unit. And, FIG. 12 is a third example diagram for explaining the performance of the laser signal generation module constituting the heating unit.

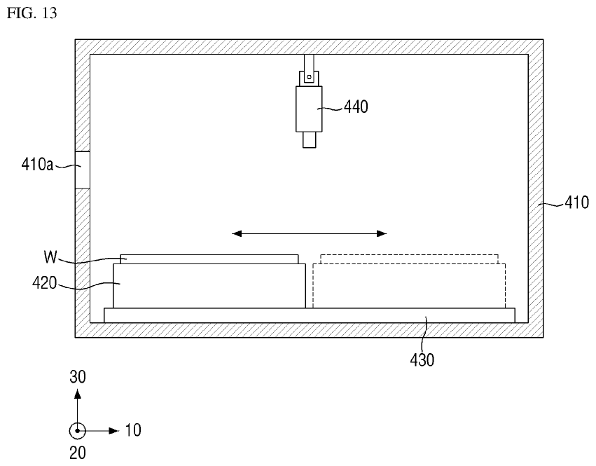

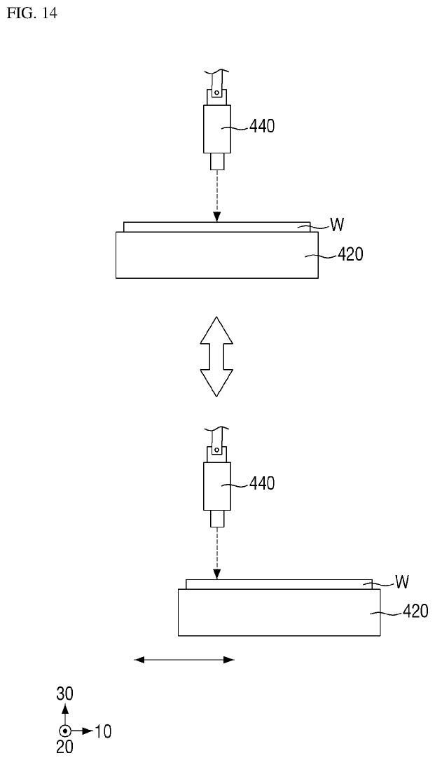

As described above, the stage 430 can freely move the support module 420 within the chamber 410. That is, the support module 420 can move on the stage 430 as shown in the example of FIG. 13. The laser signal generation module 440 can heat a desired area on the semiconductor substrate W as shown in the example of FIG. 14 according to this operation of the support module 420. The laser signal generation module 440 may be fixed to the ceiling of the chamber 410, but is not limited to this and may also be rotatable.

In the above, the stage 430 may include a driving module including a motor. In this case, the stage 430 can drive a motor to move the support module 420 installed on its top from one direction to the other. However, it is not limited to this, and the support module 420 may also include a driving module including a motor. In this case, the support module 420 may drive a motor to move from one side of the stage 430 to the other side. FIG. 13 is a first example diagram for explaining the performance of the support module and stage constituting the heating unit. And, FIG. 14 is a second example diagram for explaining the performance of the support module and stage constituting the heating unit.

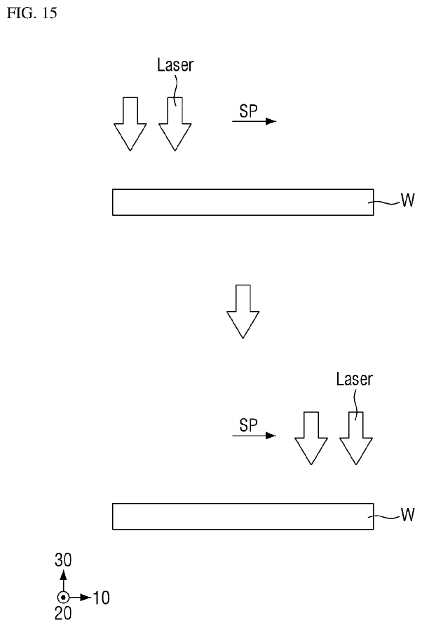

As shown in the example of FIG. 15, the laser signal generation module 440 starts processing from one end of the semiconductor substrate W and sequentially processes until the other end in order to process the entire surface of the semiconductor substrate W. In this case, as explained through the examples of FIGS. 11 and 12, the laser signal generation module 440 rotates and moves so that the entire surface of the semiconductor substrate W from one end of the semiconductor substrate W to the other end can be processed. Alternatively, as explained through the examples of FIGS. 13 and 14, the support module 420 may move in straight line on the stage 430 to process the entire surface of the semiconductor substrate W from one end of the semiconductor substrate W to the other end. FIG. 15 is an example diagram for explaining a method of processing a semiconductor substrate according to the operation of a laser signal generation module or stage. In FIG. 15, SD refers to the laser scan direction on the semiconductor substrate W.

With reference to FIGS. 6 to 15, the heating unit 220 including the laser signal generation module 440, that is, the substrate processing apparatus using a laser, has been described. The substrate processing apparatus is an apparatus for heating photoresist, and can selectively heat the photoresist by irradiating a laser signal of a specific wavelength onto the semiconductor substrate W.

Additionally, a substrate processing apparatus using a laser may also have the following features.

First, a substrate including a base substrate, an etched layer formed on the base substrate, and a photoresist disposed on the etched layer is placed on a rotary chuck, and a photoresist film is formed by providing photoresist on the substrate while rotating the rotary chuck. And then, the substrate processing apparatus may heat the photoresist film by irradiating a laser having a wavelength of 3 μm to 50 μm.

Second, it is possible to selectively and directly heat a specific layer among multiple layers through laser incident in a specific wavelength band (Mid-IR, 3 μm˜50 μm).

Third, even when the structure has a multi-layer thin film deposited, only the target polymer thin film can be selectively heated.

Fourth, even if the target PR thin film is a PR containing a metal component, direct baking is possible if it contains a polymer.

Fifth, it can replace all baking processes such as the soft baking process, hard baking process, and PEB process, which directly heat the semiconductor substrate W through conduction.

As previously described with reference to FIGS. 1 and 2, the semiconductor manufacturing equipment 100 may include a plurality of process chambers 150, and among the plurality of process chambers 150, one type of process chamber 150 may be a substrate processing apparatus 150a that performs a heat treatment process on the semiconductor substrate W, and the other type of process chamber 150 may be a substrate processing apparatus 150b that performs a coating or developing process on the semiconductor substrate W. In this case, the semiconductor manufacturing equipment 100 may be a spinner equipment.

Previously, the substrate processing apparatus 150a performing the heat treatment process was defined as the first substrate processing apparatus 150a, and the substrate processing apparatus 150b performing the coating process or developing process was defined as the second substrate processing apparatus 150b. The following explanation will follow this definition.

The first substrate processing apparatus 150a and the second substrate processing apparatus 150b may be formed by stacking a plurality of them in the height direction (third direction 30) within the semiconductor manufacturing equipment 100. For example, the floor number of equipment within the semiconductor manufacturing equipment 100 may have six floors, and in this case, the plurality of first substrate processing apparatuses 150a and the plurality of second substrate processing apparatuses 150b may be configured as follows.

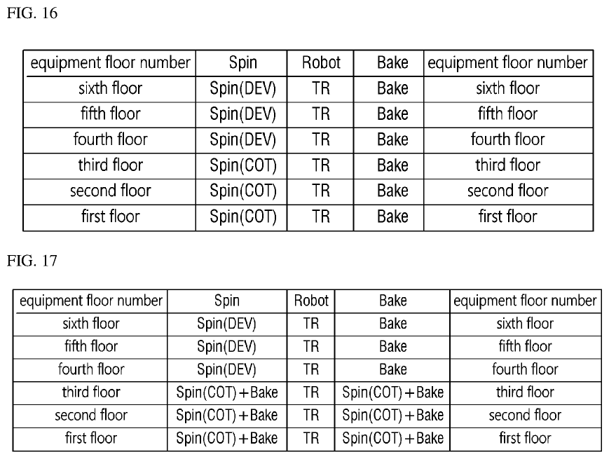

With the transfer module 140 in between, a plurality of first substrate processing apparatuses 150a may be disposed on one side, and a plurality of second substrate processing apparatuses 150b may be disposed on the other side. Referring to the example of FIG. 16, a plurality of first substrate processing apparatuses 150a, that is, a plurality of bakes, may be stacked and installed on one side of the transfer module 140 from the first to the sixth floor, and a plurality of second substrate processing apparatuses 150b may be stacked and installed on the other side of the transfer module 140 from the first to the sixth floor.

In the case of the plurality of second substrate processing apparatuses 150b, substrate processing apparatuses that perform a coating process on the semiconductor substrate W, that is, Spin (COT), may be stacked and installed from the first to the third floor according to the flow of the substrate processing process. In addition, from the fourth to the sixth floor, substrate processing apparatuses that perform a development process on the semiconductor substrate W, that is, Spin (DEV), may be stacked and installed. However, it is not limited to this, and it is also possible to stack and install Spin (DEV) from the first to the third floor, and stack and install Spin (COT) from the fourth to the sixth floor. Alternatively, it is possible for Spin (COT) to be installed on odd-numbered floors (first, third, and fifth floors) and Spin (DEV) to be installed on even-numbered floors (second, fourth, and sixth floors).

Meanwhile, TR refers to a substrate transport robot 140b provided in the transfer module 140. FIG. 16 is a first example diagram for explaining various arrangement structures of a plurality of process chambers in a semiconductor manufacturing equipment.

In some of the plurality of floors, the first substrate processing apparatus 150a and the second substrate processing apparatus 150b may be arranged side by side on one side of the transfer module 140. For example, a substrate processing apparatus (Bake) that performs a heat treatment process on the semiconductor substrate W and a substrate processing apparatus (Spin (COT)) that performs a coating process on the semiconductor substrate W can be arranged side by side on one side of the transfer module 140. Alternatively, a substrate processing apparatus (Bake) that performs a heat treatment process on the semiconductor substrate W and a substrate processing apparatus (Spin (DEV)) that performs a development process on the semiconductor substrate W may be arranged side by side on one side of the transfer module 140.

In the former case, referring to the example of FIG. 17, from the first to the third floor, a substrate processing apparatus (Bake) that performs a heat treatment process and a substrate processing apparatus (Spin (COT)) that performs a coating process may be arranged side by side on both sides of the transfer module 140. And, from the fourth to sixth floor, a substrate processing apparatus (Bake) that performs a heat treatment process may be arranged on one side of the transfer module 140, and a substrate processing apparatus (Spin (DEV)) that performs a developing process may be arranged on the other side of the transfer module 140.

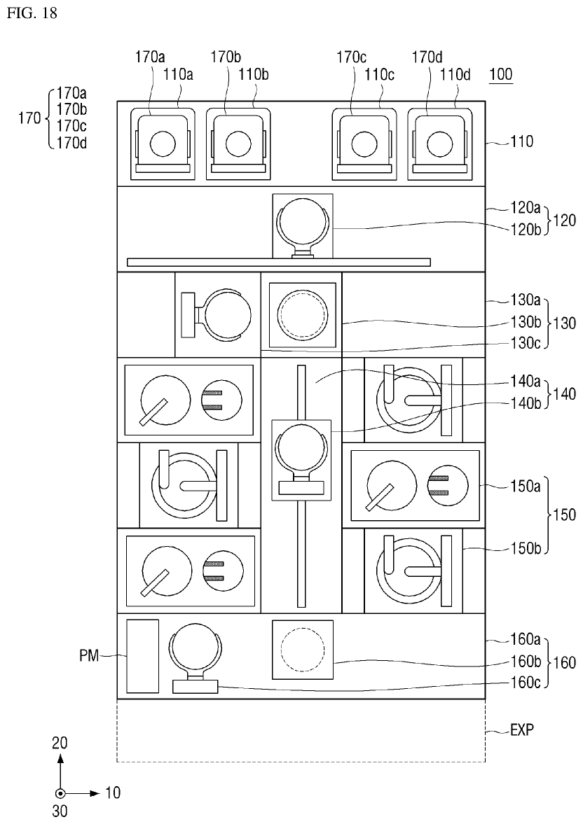

That is, the first to third floors may have the arrangement structure as shown in FIG. 18, and the fourth to sixth floors may have the arrangement structure as shown in FIG. 1. FIG. 17 is a second example diagram for explaining various arrangement structures of a plurality of process chambers in a semiconductor manufacturing equipment. And, FIG. 18 is a third example diagram for explaining various arrangement structures of a plurality of process chambers in a semiconductor manufacturing equipment.

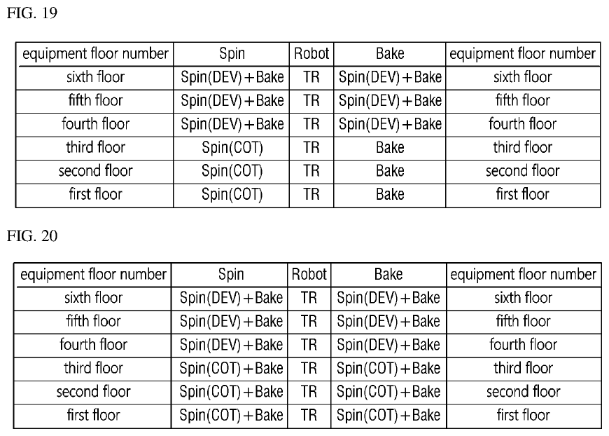

In the latter case, referring to the example of FIG. 19, from the first to third floors, a substrate processing apparatus (Bake) that performs a heat treatment process may be arranged on one side of the transfer module 140, and a substrate processing apparatus (Spin (COT)) that performs a coating process may be arranged on the other side of the transfer module 140. And from the fourth to sixth floors, a substrate processing apparatus (Bake) that performs a heat treatment process and a substrate processing apparatus (Spin (DEV)) that performs a developing process may be arranged side by side on both sides of the transfer module 140.

That is, the first to third floors may have the arrangement structure as shown in FIG. 1, and the fourth to sixth floors may have the arrangement structure as shown in FIG. 18. FIG. 19 is a fourth example diagram for explaining various arrangement structures of a plurality of process chambers in a semiconductor manufacturing equipment.

In the previous description, one type of substrate processing apparatus (Spin (COT) or Spin (DEV)) among a substrate processing apparatus (Spin (COT)) that performs a coating process and a substrate processing apparatus (Spin (DEV)) that performs a developing process, and the substrate processing apparatus (Bake) that performs the heat treatment process are arranged side by side on both sides of the transfer module 140. However, it is not limited to this, and both the substrate processing apparatus (Spin (COT)) that performs the coating process and the substrate processing apparatus (Spin (DEV)) that performs the developing process may be arranged side by side on both sides of the transfer module 140 along with the substrate processing apparatus (Bake) that perform the heat treatment process.

Referring to the example of FIG. 20, from the first to the third floor, a substrate processing apparatus (Bake) that performs a heat treatment process and a substrate processing apparatus (Spin (COT)) that performs a coating process may be arranged side by side on both sides of the transfer module 140. In addition, from the fourth to sixth floors, a substrate processing apparatus (Bake) that performs a heat treatment process and a substrate processing apparatus (Spin (DEV)) that performs a development process may be arranged side by side on both sides of the transfer module 140.

That is, the first to sixth floors may have the arrangement structure as shown in FIG. 18. FIG. 20 is a fifth example diagram for explaining various arrangement structures of a plurality of process chambers in a semiconductor manufacturing equipment.

As described above with reference to FIGS. 17 to 20, the semiconductor manufacturing equipment 100 can diversify an equipment layout structure using laser bake that does not cause side effects due to heat conduction and convection phenomena. According to these various structures of the semiconductor manufacturing equipment 100, when the first substrate processing apparatus (Bake) and the second substrate processing apparatus (Spin (COT0, Spin (DEV)) are arranged in one unit, the effect of increasing the number of semiconductor substrates processed per unit time due to path optimization can be obtained.

Although the embodiments of the present disclosure have been described with reference to the above and accompanying drawings, those skilled in the art to which the present disclosure pertains can understand that the present disclosure can be practiced in other specific forms without changing the technical concept or essential features. Therefore, the embodiments described above should be understood as illustrative in all respects and not limiting.

What is claimed is:

1. An apparatus for processing a substrate comprising:
a chamber for providing a space where a substrate is processed;
a support module disposed within the chamber and for supporting the substrate; and
a laser signal generation module disposed in the chamber and for transmitting a laser signal onto the substrate to heat-treat the substrate,
wherein the laser signal generation module heat-treats the substrate including a photoresist layer.

2. The apparatus of claim 1, wherein the substrate includes a plurality of layers,
wherein the laser signal generation module selectively heats some layers among the plurality of layers.

3. The apparatus of claim 2, wherein the some layers include the photoresist layer and a polymer layer.

4. The apparatus of claim 2, wherein the plurality of layers do not include a metal layer.

5. The apparatus of claim 1, wherein the laser signal generation module transmits a laser signal in a Mid-IR band.

6. The apparatus of claim 1, wherein the laser signal has a wavelength of 3 μm to 50 μm.

7. The apparatus of claim 1, wherein the laser signal generation module incidents the laser signal on the substrate in a first direction,
wherein the first direction is perpendicular to a width direction of the substrate.

8. The apparatus of claim 1, wherein a laser signal emission angle of the laser signal generation module is variable.

9. The apparatus of claim 8 further comprises,
a camera module disposed in the chamber and for photographing the substrate,
wherein the laser signal emission angle varies depending on a photographing result of the camera module.

10. The apparatus of claim 1 further comprises,
a stage provided below the support module within the chamber,
wherein the support module is moved on the stage.

11. The apparatus of claim 1, wherein a scanning direction of the laser signal is perpendicular to an emission direction of the laser signal.

12. The apparatus of claim 1, wherein the laser signal generation module comprises,
a first laser diode for generating and outputting a first laser signal;
a second laser diode for generating and outputting a second laser signal;
a pump combiner for combining the first laser signal and the second laser signal;
an external transmission part for transmitting a combined laser signal obtained by combining the first laser signal and the second laser signal to an outside; and
a plurality of optical fibers for interconnecting the first laser diode and the pump combiner, the second laser diode and the pump combiner, and the pump combiner and the external transmission part.

13. The apparatus of claim 12, wherein the plurality of optical fibers comprises,
a first optical fiber for connecting the first laser diode and the pump combiner;
a second optical fiber, a third optical fiber, and a fourth optical fiber for connecting the second laser diode and the pump combiner; and
a fifth optical fiber and a sixth optical fiber for connecting the pump combiner and the external transmission part.

14. The apparatus of claim 13, wherein the second optical fiber, the third optical fiber, and the fourth optical fiber include a material of the same component.

15. The apparatus of claim 13, wherein at least one of the third optical fiber and the fourth optical fiber has a different shape from the second optical fiber.

16. The apparatus of claim 13, wherein the fifth optical fiber and the sixth optical fiber include materials of different components.

17. The apparatus of claim 1, wherein the laser signal generation module uses a fluoride fiber laser or CO2 laser as a light source.

18. A semiconductor manufacturing equipment comprising:
a transfer module including a substrate transport robot for transporting a substrate;
a plurality of first substrate processing apparatuses disposed on one side of the transfer module; and
a plurality of second substrate processing apparatuses disposed on the other side of the transfer module,
wherein the first substrate processing apparatus comprises,
a chamber for providing a space where a substrate is processed;
a support module disposed within the chamber and for supporting the substrate; and
a laser signal generation module disposed in the chamber and for transmitting a laser signal onto the substrate to heat-treat the substrate,
wherein the laser signal generation module heat-treats the substrate including a photoresist layer.

19. The equipment of claim 18, wherein the second substrate processing apparatus includes a third substrate processing apparatus for performing a coating process on the substrate and a fourth substrate processing apparatus for performing a developing process on the substrate,
wherein the first substrate processing apparatus is arranged side by side on the same floor and on the same side as at least one of the third substrate processing apparatus and the fourth substrate processing apparatus.

20. An apparatus for processing a substrate comprising:
a chamber for providing a space where a substrate is processed;
a support module disposed within the chamber and for supporting the substrate; and
a laser signal generation module disposed in the chamber and for transmitting a laser signal onto the substrate to heat-treat the substrate,
wherein the substrate includes a plurality of layers,
wherein the laser signal generation module selectively heats some layers among the plurality of layers, and the some layers include the photoresist layer and a polymer layer,
wherein the laser signal generation module transmits a laser signal in a Mid-IR band, and the laser signal has a wavelength of 3 μm to 50 μm,
wherein the laser signal generation module incidents the laser signal on the substrate in a first direction, where the first direction is perpendicular to a width direction of the substrate,
wherein a scanning direction of the laser signal is perpendicular to an emission direction of the laser signal.
